(19) United States
(12) Patent Application Publication
(10) Pub. No.: US 2025/0391645 A1
(43) Pub. Date: Dec. 25, 2025

(54) PLASMA PROCESSING APPARATUS AND PLASMA PROCESSING METHOD

(71) Applicant: Panasonic Intellectual Property Management Co., Ltd., Osaka (JP)

(72) Inventors: Toshiyuki TAKASAKI, OSAKA (JP); Shogo OKITA, HYOGO (JP); Hidehiko KARASAKI, HYOGO (JP); Seiya NAGANO, OSAKA (JP); Hisao NAGAI, OSAKA (JP)

(21) Appl. No.: 19/239,004

(22) Filed: Jun. 16, 2025

(30) Foreign Application Priority Data
Jun. 19, 2024 (JP) 2024-098876

(51) Int. Cl. H01J 37/32

(52) U.S. Cl. CPC H01J 37/32724; H01J 37/32449; H01J 2237/3321; H01J 2237/3346

(57) ABSTRACT

A plasma processing apparatus includes a chamber, a stage, provided in the chamber, on which the substrate is to be placed, a sensor that receives the infrared rays emitted from the substrate placed on the stage and that outputs a measurement value corresponding to the intensity of the received infrared rays, and a determination section that determines occurrence or non-occurrence of a temperature abnormality in the substrate based on the measurement value. When a state in which a time rate of change of the measurement value exceeds a first threshold value persists for a period longer than a threshold time, the determination section performs first determination processing of determining that a temperature abnormality in the substrate has occurred.

### CROSS REFERENCE TO RELATED APPLICATION

The present application is based on and claims priority under 35 U.S.C. § 119 with respect to the Japanese Patent Application No. 2024-098876, filed on Jun. 19, 2024, of which entire content is incorporated herein by reference into the present application.

### TECHNICAL FIELD

The present disclosure relates to a plasma processing apparatus and a plasma processing method.

### BACKGROUND

Conventionally, plasma processing apparatuses have been known that perform plasma processing on an object to be processed such as a substrate (e.g., a Japanese Laid-Open Patent Publication No. 2018-006758). Japanese Laid-Open Patent Publication No. 2018-006758 discloses “a plasma dicing apparatus including: a chamber; a substrate support section for supporting a non-metal substrate of a type having a dicing lane; a plasma generator for generating in the chamber plasma suitable for plasma etching on the substrate along the dicing lane; an infrared detector for monitoring the infrared rays emitted from at least a part of the dicing lane; and a state detector configured to detect the state associated with the final stage of a plasma dicing process from the monitored infrared rays.

When a temperature abnormality (e.g., an abnormal temperature rise) of the substrate occurs during plasma processing, damage to the substrate can be minimized by quickly suspending the plasma processing. Accordingly, it is desired to develop a technique for detecting temperature abnormalities in substrates with high accuracy.

### SUMMARY

One aspect of the present disclosure relates to a plasma processing apparatus. The plasma processing apparatus includes: a chamber; a stage, provided in the chamber, on which a substrate is to be placed; a sensor that receives infrared rays emitted from the substrate placed on the stage and that outputs a measurement value corresponding to an intensity of the received infrared rays; and a determination section that determines occurrence or non-occurrence of a temperature abnormality in the substrate based on the measurement value, wherein the determination section performs first determination processing of determining that a temperature abnormality in the substrate has occurred when a state in which a time rate of change of the measurement value exceeds a first threshold value persists for a period longer than a threshold time.

Another aspect of the present disclosure relates to a plasma processing method. The plasma processing method is a plasma processing method that is executed by a plasma processing apparatus including: a chamber; a stage, provided in the chamber, on which a substrate is to be placed; and a sensor that receives infrared rays emitted from the substrate placed on the stage and that outputs a measurement value corresponding to an intensity of the received infrared rays, the method including a first determination step of determining that a temperature abnormality in the substrate has occurred when a state in which a time rate of change of the measurement value exceeds a first threshold value persists for a period longer than a threshold time.

### BRIEF DESCRIPTION OF THE DRAWINGS

FIG. 1 is a schematic cross-sectional view of an example of a plasma processing apparatus according to the present disclosure.

FIG. 2 presents an example of graphs depicting the relationship between sensor measurement values and processing time during plasma processing, and corresponds to a case where unit processing is normally repeated.

FIG. 3 presents an example of graphs depicting the relationship between the sensor measurement values and the processing time during plasma processing, and corresponds to a case where a temperature abnormality in a substrate occurs.

FIG. 4 presents an example of graphs depicting the relationship between sensor measurement values and the processing time during plasma processing, and corresponds to a case where a temperature abnormality in a substrate occurs.

### DETAILS DESCRIPTION

Embodiments of a plasma processing apparatus and a plasma processing method according to the present disclosure will be described below. However, the present disclosure is not limited to the examples described below. In the following description, specific numerical values and materials may be exemplified in some cases, but other numerical values and other materials may be adopted as long as the effects of the present disclosure can be obtained.

### (Plasma Processing Apparatus)

The plasma processing apparatus according to the present disclosure is an apparatus that performs plasma processing on a substrate as an object to be processed. The plasma processing apparatus may be a plasma etching apparatus, a plasma dicer, a plasma ashing apparatus, or a plasma CVD apparatus, for example. The plasma processing apparatus includes a chamber, a stage, a sensor, and a determination section.

The chamber may have an opening at the top. The opening may open upward. The chamber may be formed in a hollow cylindrical shape. The chamber may be made of metal and may be grounded.

The stage is provided in the chamber and the substrate is to be placed thereon. The stage may have a horizontal placement surface on which the substrate is to be placed. The stage may have a flow path through which a refrigerant for cooling the substrate flows during plasma processing. The stage may include an electrostatic chuck mechanism for chucking the substrate. The stage may have a lower electrode to which high-frequency power is applied. The substrate may be a semiconductor substrate that is singulated by plasma etching, for example. The semiconductor substrate has a plurality of element regions and a division region defining the element regions. The element regions each include a semiconductor layer and a wiring layer, for example. By etching the division region, element chips each including the semiconductor layer and the wiring layer can be obtained. The substrate may be placed on the stage with it supported by a carrier. The carrier may be a resin sheet whose outer periphery is held by a frame, for example.

The sensor receives the infrared rays emitted from the substrate placed on the stage. The sensor outputs a measurement value corresponding to the intensity of the received infrared rays. The mode of outputting the measurement value is not particularly limited, and a voltage having a magnitude corresponding to the intensity of the received infrared rays may be output, for example. The intensity of the infrared rays emitted from the substrate can increase as the temperature of the substrate is increased.

The determination section determines occurrence or non-occurrence of a temperature abnormality in the substrate based on the measurement value output from the sensor. Specifically, when the state in which the time rate of change of the measurement value (i.e., an amount of change of the measurement value per unit time) exceeds a first threshold value persists for a period longer than a threshold time, the determination section determines that a temperature abnormality in the substrate has occurred. The determination section may be included in a control device included in the plasma processing apparatus, or may be included in a device (e.g., an information processing device) separate from the plasma processing apparatus. The first threshold value may be, for example, 2° C./sec or more when the measurement value is converted into a temperature of the substrate. The threshold time may be 2 seconds or longer and 5 seconds or shorter, for example.

As a result of intensive research, it has been found that, according to this determination mode, temperature abnormalities in substrates can be detected with high accuracy. That is, it was found that, when a measurement value of the sensor is directly compared with a certain threshold value for temperature abnormality detection, the measurement value of the sensor exceeds the threshold value depending on the type of the substrate or the type of the plasma processing, which may induce erroneous detection of a temperature abnormality, even when no temperature abnormalities in the substrate has occurred. To tackle this, the research focused on the time rate of change of the measurement value of the sensor and examined determination that a temperature abnormality in the substrate has occurred when the time rate of change exceeds the first threshold value. As a result, it was found that, depending on the type of the plasma processing, the time rate of change may temporarily exceed the first threshold value even when no temperature abnormalities in the substrate occur, and this can also induce erroneous temperature abnormality detection. Further, as a result of further research being conducted, it was found that temperature abnormalities in the substrate can be appropriately detected while avoiding erroneous detection of temperature abnormalities through determination that a temperature abnormality in the substrate has occurred when the state in which the time rate of change of the measurement value of the sensor exceeds the first threshold value persists for a period longer than a threshold time.

The determination section may perform second determination processing of determining that a temperature abnormality in the substrate has occurred when the measurement value exceeds a second threshold value. Performance of the second determination processing such as above on the premise that first determination processing is performed makes it possible to further improve accuracy of substrate temperature abnormality detection. That is, although a temperature abnormality in which gradual increase of the measurement value of the sensor (or the temperature of the substrate) continues cannot be detected in the first determination processing, a temperature abnormality such as above can be detected by performing the second determination processing without failure. The second threshold value may be, for example, 80° C. or higher when the measurement value is converted into a temperature of the substrate.

The plasma processing apparatus may further include a plasma generation section that generates plasma in the chamber, a gas supply section that supplies a feed gas of the plasma into the chamber, and an operation control section that controls the plasma generation section and the gas supply section. The operation control section may control, after first plasma is generated in the chamber, the plasma generation section and the gas supply section to perform a switching operation for generating second plasma different from the first plasma in the chamber. The determination section may perform the first determination processing in a period including the timing at which the switching operation is performed. In this configuration, a temperature abnormality in the substrate can be appropriately detected while avoiding erroneous detection through the first determination processing in a period including the timing at which the switching operation is performed, that is, in a period when the measurement value can greatly fluctuate even during normal operation. The operation control section may be included in a control device included in the plasma processing apparatus.

The operation control section may control the plasma generation section and the gas supply section to repeat unit processing including a plurality of steps. The determination section may perform the first determination processing in a period including a period in which the unit processing is repeated. In this configuration, through the first determination processing being performed, temperature abnormalities in the substrate can be appropriately detected while avoiding erroneous detection in a period in which the unit processing is repeated, that is, in a period in which the measurement value can fluctuate greatly and repeatedly even during normal operation.

The unit processing may include a deposition step of depositing a protective film on a surface of the substrate, a protective film removal step of removing a part of the protective film to expose a part of the substrate, and an etching step of etching the part of the substrate that has been exposed. Repetition of the unit processing as above can make it possible to dig the substrate deep by a generally-called Bosch process. Through the first determination processing, temperature abnormalities in the substrate can be appropriately detected while avoiding erroneous detection even when the Bosch process is performed, that is, even when the measurement value fluctuates greatly and repeatedly within a short period of time.

The threshold time may be longer than the shortest one of the processing times of the plurality of steps. For example, when the shortest processing time is 2 seconds, the threshold time may be 2.5 seconds or longer and 5 seconds or shorter.

### (Plasma Processing Method)

The plasma processing method according to the present disclosure may be executed by the above-described plasma processing apparatus, but is executable also by a plasma processing apparatus that does not include the determination section. The plasma processing method is a method executed by a plasma processing apparatus including the above-described stage and the above-described sensor, and includes a first determination step.

In the first determination step, when a state in which the time rate of change of the measurement value output from the sensor exceeds a first threshold value persists for a period longer than a threshold time, it is determined that a temperature abnormality in the substrate has occurred. Thus, temperature abnormalities in the substrate can be detected with high accuracy. In a case where the plasma processing apparatus includes the above-described determination section, the first determination step may be executed by the determination section. In a case where the plasma processing apparatus does not include the above-described determination section by contrast, the first determination step may be executed by a device (e.g., an information processing device) separate from the plasma processing apparatus.

The plasma processing method may further include a second determination step of determining that a temperature abnormality in the substrate has occurred when the measurement value exceeds a second threshold value. Thus, accuracy of substrate temperature abnormality detection can be further improved.

The plasma processing apparatus may further include a plasma generation section that generates plasma in the chamber, and a gas supply section that supplies a feed gas of the plasma into the chamber. The plasma processing method may further include an operation control step of controlling, after first plasma is generated in the chamber, the plasma generation section and the gas supply section to perform a switching operation for generating second plasma different from the first plasma in the chamber. The first determination step may be executed in a period including the timing at which the switching operation is performed. In this configuration, temperature abnormalities in the substrate can be appropriately detected while avoiding erroneous detection through the first determination step in a period including the timing at which the switching operation is performed, that is, in a period in which the measurement value can greatly fluctuate even during normal operation.

In the operation control step, the plasma generation section and the gas supply section may be controlled to repeat unit processing including a plurality of steps. The first determination step may be executed in a period including a period in which the unit processing is repeated. In this configuration, temperature abnormalities in the substrate can be appropriately detected while avoiding erroneous detection through the first determination step in a period in which the unit processing is repeated, that is, in a period in which the measurement value fluctuates greatly and repeatedly even during normal operation.

The unit processing may include a deposition step of depositing a protective film on a surface of the substrate, a protective film removal step of removing a part of the protective film to expose a part of the substrate, and an etching step of etching the part of the substrate that has been exposed. In this processing, temperature abnormalities in the substrate can be appropriately detected while avoiding erroneous detection through the first determination step even when the Bosch process is performed, that is, even when the measurement value repeatedly and greatly fluctuates within a short period of time.

The threshold time may be longer than the shortest one of the processing times of the plurality of steps. For example, when the shortest processing time is 2 seconds, the threshold time may be 2.5 seconds or longer and 5 seconds or shorter.

As described above, according to the present disclosure, it is possible to detect temperature abnormalities in the substrate with high accuracy by devising an approach to utilizing the measurement values output by the sensor.

Hereinafter, exemplary plasma processing apparatus and plasma processing method according to the present disclosure will be described in detail with reference to the accompanying drawings. The above-described elements of configuration and steps can be applied to the elements of configuration and steps of the exemplary plasma processing apparatus and plasma processing method described below. The elements of configuration and steps of the exemplary plasma processing apparatus and plasma processing method described below can be altered based on the above description. Further, the matters described below may be applied to the above-described embodiment. Among the elements of configuration and steps of the exemplary plasma processing apparatus and plasma processing method described below, an element of configuration or a step that is not essential to the plasma processing apparatus or the plasma processing method according to the present disclosure may be omitted. It should be noted that the drawings indicated below are schematic and do not accurately reflect the shape or number of actual members.

### (Plasma Processing Apparatus)

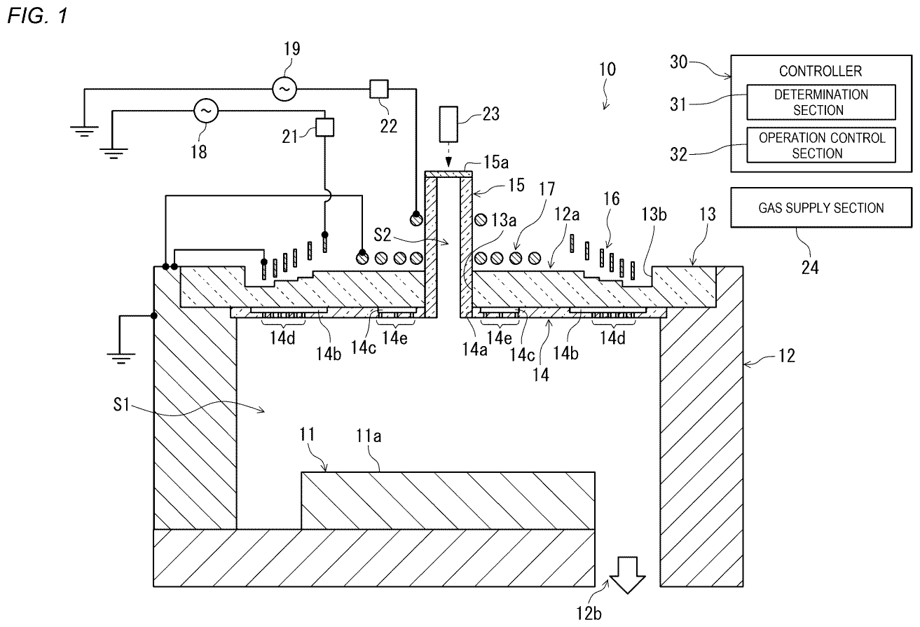

A plasma processing apparatus 10 of the present embodiment is an apparatus for performing plasma processing on a substrate (e.g., a semiconductor substrate) as an object to be processed. The plasma processing apparatus 10 of the present embodiment is a plasma dicer, but is not limited thereto. As illustrated in FIG. 1, the plasma processing apparatus 10 includes a stage 11, a chamber 12, a first dielectric member 13, a cover 14, a second dielectric member 15, a first induction coil 16, a second induction coil 17, a first high-frequency power supply 18, a second high-frequency power supply 19, a sensor 23, a gas supply section 24, and a controller 30.

The stage 11 is an element of configuration on which the substrate (not illustrated) is to be placed. The stage 11 has a horizontal placement surface 11a on which a substrate is to be placed. The stage 11 has a flow path (not illustrated) through which a refrigerant for cooling the substrate flows during plasma processing. The stage 11 includes an electrostatic chuck mechanism (not illustrated) for chucking the substrate. The stage 11 includes a lower electrode (not illustrated) to which high-frequency power is applied. Note that a temperature abnormality in the substrate may occur, for example, when chucking by the electrostatic chuck mechanism is not appropriately performed.

The chamber 12 houses the stage 11 and has a first opening 12a at the top. The chamber 12 is formed in a hollow cylindrical shape but is not limited thereto. The first opening 12a opens upward. The chamber 12 is positioned around the outer periphery of the stage 11 and has an exhaust port 12b for exhausting the feed gas used in the plasma processing. A non-illustrated exhaust system is connected to the exhaust port 12b. The chamber 12 is constituted of a conductive member (e.g., metal) and is grounded.

The first dielectric member 13 blocks the first opening 12a to define a first space S1 in the chamber 12, and has a second opening 13a. The first dielectric member 13 is formed in a plate shape extending horizontally. The first space S1 is a space in which the stage 11 is positioned. The second opening 13a passes through the first dielectric member 13 vertically. The second opening 13a is located at the central part of the first dielectric member 13. The first dielectric member 13 has a recess 13b in the upper surface thereof. The first dielectric member 13 is made of quartz, but is not limited thereto.

The cover 14 is provided so as to cover the lower surface of the first dielectric member 13. The cover 14 has a first gas introduction path 14b through which the feed gas is supplied to a region of the first space S1 that is opposed the first induction coil 16, and a second gas introduction path 14c through which the feed gas is supplied to a region of the first space S1 that is opposite the second induction coil 17. The first gas introduction path 14b and the second gas introduction path 14c are each constituted as a groove or a recess formed in the upper surface of the cover 14. The first gas introduction path 14b communicates with the outside of the chamber 12 and communicates with the first space S1 via first gas holes 14d. The second gas introduction path 14c communicates with the outside of the chamber 12 and communicates with the first space S1 via second gas holes 14e. The first gas holes 14d and the second gas holes 14e are spaced apart from each other in the circumferential direction. The first gas holes 14d and the second gas holes 14e are arranged at intervals in the radial directions (the left-right direction in FIG. 1). The first gas introduction path 14b and the second gas introduction path 14c are each formed between the cover 14 and the first dielectric member 13. The feed gas is supplied to the first gas introduction path 14b and the second gas introduction path 14c from the gas supply section 24. The cover 14 has a third opening 14a overlapping with the second opening 13a. The third opening 14a is located in a central part of the cover 14. The cover 14 is made of aluminum nitride, but is not limited thereto.

The second dielectric member 15 defines a second space S2 that communicates with the first space S1 via the second opening 13a and the third opening 14a and that extends above the first dielectric member 13. The second dielectric member 15 is fitted to the second opening 13a and the third opening 14a. The second dielectric member 15 is formed in a cylindrical shape extending vertically. The second dielectric member 15 is made of aluminum nitride, but is not limited thereto.

The second dielectric member 15 has a dielectric window 15a for optical measurement at the top. The dielectric window 15a transmits infrared rays and the like emitted from the substrate placed on the stage 11. The dielectric window 15a may be integral with or separate from the cylindrical part of the second dielectric member 15.

The first induction coil 16 extends from the central part toward the outer periphery of the first dielectric member 13 above the first dielectric member 13 and generates plasma for substrate processing. The first induction coil 16 is composed of one or more electrical conductors each extending spirally in the circumferential direction. A part of the outer periphery of the first induction coil 16 is located inside the recess 13b formed in the first dielectric member 13. The first induction coil 16 receives high-frequency power from the first high-frequency power supply 18 to generate a magnetic field. This magnetic field acts on the feed gas in the first space S1 via the first dielectric member 13, thereby generating plasma.

The second induction coil 17 is provided so as to surround the second dielectric member 15 and generates plasma for substrate processing. The second induction coil 17 has a part extending in the vertical direction along the second dielectric member 15 and a part extending in the horizontal direction along the first dielectric member 13. The former has a helical shape extending in the vertical direction, while the latter has a spiral shape extending in the horizontal direction. The second induction coil 17 is positioned inside the first induction coil 16. The second induction coil 17 receives high-frequency power from the second high-frequency power supply 19 to generate a magnetic field. This magnetic field acts on the feed gas in either or both the first space S1 and the second space S2 through the second dielectric member 15, thereby generating plasma.

The first high-frequency power supply 18 supplies high-frequency power (e.g., AC power at 3 to 30 MHz) to the first induction coil 16. The first high-frequency power supply 18 is connected to one end of the first induction coil 16 via a first matching unit 21 such as a variable capacitor. The other end of the first induction coil 16 is grounded via the chamber 12 which is conductive.

The second high-frequency power supply 19 supplies high-frequency power (e.g., AC power at 3 to 30 MHz) to the second induction coil 17. The second high-frequency power supply 19 is connected to one end of the second induction coil 17 via a second matching unit 22 such as a variable capacitor. The other end of the second induction coil 17 is grounded via the chamber 12 which is conductive.

The frequency of the power (power applied to the first induction coil 16) of the first high-frequency power supply 18 and the frequency of the power (power applied to the second induction coil 17) of the second high-frequency power supply 19 are different from each other. Note that these frequencies may be equal to each other. Alternatively, a single high-frequency power supply may be provided, instead of the first high-frequency power supply 18 and the second high-frequency power supply 19, to distribute the power thereof to the first induction coil 16 and the second induction coil 17.

The first induction coil 16, the second induction coil 17, the first high-frequency power supply 18, and the second high-frequency power supply 19 constitute a plasma generation section of the present embodiment.

The sensor 23 is provided above the dielectric window 15a and receives the infrared rays emitted from the substrate placed on the stage 11. The sensor 23 outputs a measurement value corresponding to the intensity of the received infrared rays (hereinafter, also referred to simply as measurement value). Information about the measurement value is sent to the controller 30 through wired or wireless communication.

The gas supply section 24 supplies the feed gas of plasma into the chamber 12. The gas supply section 24 is connected to the first gas introduction path 14b and the second gas introduction path 14c via a non-illustrated gas pipe. The gas supply section 24 is configured to be able to switch the type of the feed gas to be supplied so that the type of plasma generated in the chamber 12 is switchable.

The controller 30 includes a determination section 31 and an operation control section 32. The controller 30 includes an arithmetic unit and a storage device that stores therein programs (e.g., a program for executing the plasma processing method of the present embodiment) executable by the arithmetic unit. The controller 30 is configured to exhibit the functions of the determination section 31 and the operation control section 32 through the arithmetic unit executing the program.

The determination section 31 determines occurrence or non-occurrence of a temperature abnormality in the substrate based on a measurement value T output from the sensor 23. That is, the determination section 31 performs first determination processing and second determination processing. Here, the first determination processing is processing of determining that a temperature abnormality in the substrate has occurred when a state in which a time rate ΔT of change of the measurement value T exceeds a first threshold value ΔT_th persists for a period longer than a threshold time t_th. The second determination processing is processing of determining that a temperature abnormality in the substrate has occurred when the measurement value T exceeds a second threshold value T_th. In the present embodiment, the second determination processing is performed when no temperature abnormalities in the substrate is detected in the first determination processing. When a temperature abnormality in the substrate is detected in the first determination processing or the second determination processing, it is determined that a temperature abnormality in the substrate has occurred. While on the other hand, when no temperature abnormalities in the substrate is detected in the first determination processing and the second determination processing, it is determined that no temperature abnormalities in the substrate has occurred. The first determination processing and the second determination processing may be performed in real time at predetermined time intervals (e.g., every second) during plasma processing. The threshold time t_th in the present embodiment is longer than the processing time of a step with the shortest one of the processing times of the deposition step, the protective film removal step, and the etching step, which will be described later.

The operation control section 32 controls the plasma generation section (more specifically, the first high-frequency power supply 18 and the second high-frequency power supply 19) and the gas supply section 24. That is, the operation control section 32 controls, after first plasma is generated in the chamber 12, the plasma generation section and the gas supply section 24 to perform a switching operation for generating second plasma different from the first plasma in the chamber 12. For example, the first plasma and the second plasma can be generated in the chamber 12 by changing the outputs of the first high-frequency power supply 18 and the second high-frequency power supply 19 and the type and flow rate of the feed gas supplied by the gas supply section 24.

More specifically, the operation control section 32 controls the plasma generation section and the gas supply section 24 to execute the Bosch process. That is, the operation control section 32 controls the plasma generation section and the gas supply section 24 so as to repeat unit processing including a deposition step of depositing a protective film on a surface of the substrate, a protective film removal step of removing a part of the protective film to expose a part of the substrate, and an etching step of etching the part of the substrate that has been exposed. The plasma used in the deposition step is an example of the first plasma. The plasma used in the protective film removal step is an example of the second plasma. The plasma used in the etching step is an example of third plasma. That is, the switching operation in the present embodiment includes a first switching operation for switching plasma from the first plasma to the second plasma, a second switching operation for switching plasma from the second plasma to the third plasma, and a third switching operation for switching plasma from the third plasma to the first plasma. Further, in the present embodiment, the first to third switching operations are repeatedly performed until the number of times of repetitive execution of the unit processing reaches a predetermined number of times.

The determination section 31 performs the first determination processing in a period including a period in which the unit processing is repeated. In other words, the first determination processing is continuously performed at predetermined time intervals during the time when the unit processing is repeatedly performed. Therefore, the first determination processing is performed in a period including the timing at which a switching operation (in this example, the first to third switching operations) is performed.

### (Plasma Processing Method)

A plasma processing method of the present embodiment is executable, for example, by the plasma processing apparatus 10 of the present embodiment, and includes an operation control step, a first determination step, and a second determination step.

In the operation control step, the operation control section 32 controls the plasma generation section and the gas supply section 24 so as to repeat the unit processing including the deposition step, the protective film removal step, and the etching step. Preferably, the operation control step is started after a start of the first determination step.

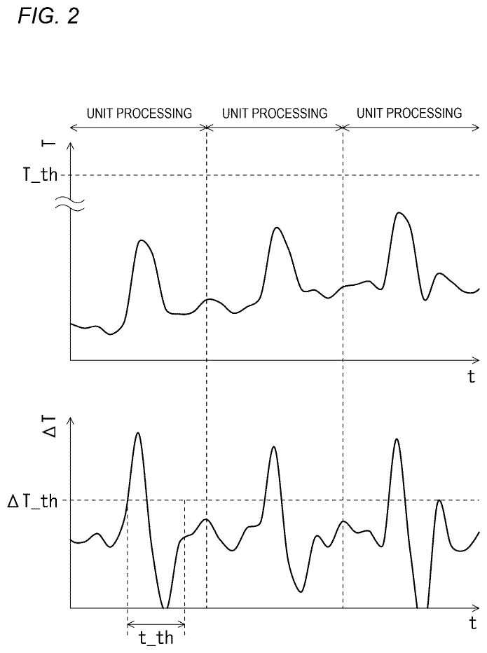

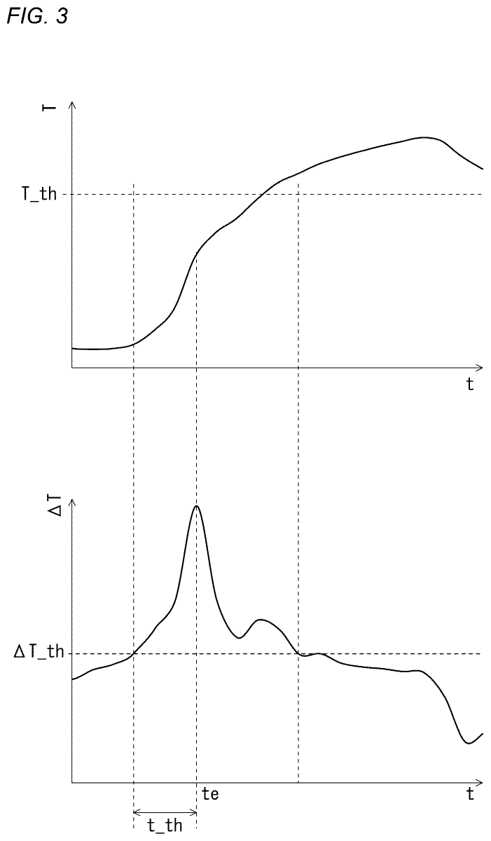

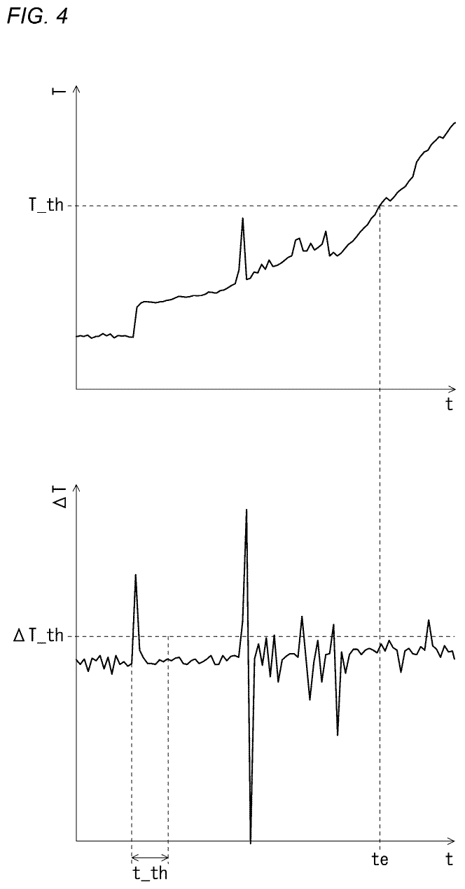

When each step is normally executed without a temperature abnormality in the substrate occurring, the relationship between the measurement value T (or the temperature of the substrate) and processing time is as shown in the graphs of FIG. 2, for example. In a case where a temperature abnormality in the substrate occurs, the relationship between the measurement value T and the processing time is as shown in the graphs of FIG. 3 or FIG. 4, for example. Note that the graphs of FIGS. 3 and 4 are not graphs corresponding to plasma processing in which the unit processing is repeatedly performed.

In the first determination step, the determination section 31 performs the first determination processing described above. In the example of FIG. 2, although the time rate ΔT of change of the measurement value T temporarily exceeds the first threshold value ΔT_th, no temperature abnormalities in the substrate is detected in the first determination step and the plasma processing is continued since the duration of such a state is shorter than the threshold time t_th. By contrast, in the example of FIG. 3, since the state in which the time rate ΔT of change of the measurement value T exceeds the first threshold value ΔT_th persists for a period longer than the threshold time t_th, a temperature abnormality in the substrate is detected at a time the in the first determination step and the plasma processing is suspended. Further, in the example of FIG. 4, although the time rate ΔT of change of the measurement value T temporarily exceeds the first threshold value ΔT_th, no temperature abnormalities in the substrate is detected in the first determination step and the plasma processing is continued since the duration of such a state is shorter than the threshold time t_th.

In the second determination step, the determination section 31 performs the second determination processing described above. In the example of FIG. 2, although the measurement value T increases in each unit processing, no temperature abnormalities in the substrate is detected also in the second determination step and the plasma processing is continued, since the maximum value thereof is less than the second threshold value T_th. By contrast, in the example of FIG. 3, the measurement value T exceeds the second threshold value T_th, but the timing thereof is later than the timing (time the) at which a temperature abnormality in the substrate is detected in the first determination step. Therefore, in the example of FIG. 3, the plasma processing is suspended before the second determination processing is performed in practice in response to the occurrence of the temperature abnormality in the substrate through the first determination processing. Further, in the example of FIG. 4, since the measurement value T exceeds the second threshold value T_th, a temperature abnormality in the substrate is detected at the time the in the second determination step, and the plasma processing is suspended at the time the. Note that the second determination step may be executed only when no temperature abnormalities in the substrate are detected in the first determination step, or may be executed regardless of the result of determination in the first determination step.

### <<Supplemental Remarks>>

According to the above description of the embodiments, the following techniques are disclosed.

### (Technique 1)

A plasma processing apparatus including:
a chamber;
a stage, provided in the chamber, on which a substrate is to be placed;
a sensor that receives infrared rays emitted from the substrate placed on the stage and that outputs a measurement value corresponding to an intensity of the received infrared rays; and
a determination section that determines occurrence or non-occurrence of a temperature abnormality of the substrate based on the measurement value,
wherein the determination section performs first determination processing of determining that a temperature abnormality of the substrate has occurred when a state in which a time rate of change of the measurement value exceeds a first threshold value persists for a period longer than a threshold time.

### (Technique 2)

The plasma processing apparatus according to Technique 1, wherein when the measurement value exceeds a second threshold value, the determination section performs second determination processing of determining that a temperature abnormality of the substrate has occurred.

### (Technique 3)

The plasma processing apparatus according to Technique 1 or 2, further including:
a plasma generation section that generates plasma in the chamber;
a gas supply section that supplies a feed gas of the plasma into the chamber; and
an operation control section that controls the plasma generation section and the gas supply section,
wherein the operation control section controls, after first plasma is generated in the chamber, the plasma generation section and the gas supply section to perform a switching operation for generating second plasma different from the first plasma in the chamber, and
the determination section performs the first determination processing in a period including a timing at which the switching operation is performed.

### (Technique 4)

The plasma processing apparatus according to Technique 3, wherein the operation control section controls the plasma generation section and the gas supply section to repeat unit processing including a plurality of steps, and
the determination section performs the first determination processing in a period including a period in which the unit processing is repeated.

### (Technique 5)

The plasma processing apparatus according to Technique 4, wherein the unit processing includes:
a deposition step of depositing a protective film on a surface of the substrate;
a protective film removal step of removing a part of the protective film to expose a part of the substrate; and
an etching step of etching the part of the substrate that has been exposed.

### (Technique 6)

The plasma processing apparatus according to Technique 4 or 5, wherein the threshold time is longer than a shortest one of processing times of the plurality of steps.

### (Technique 7)

A plasma processing method that is executed by a plasma processing apparatus including:
a chamber;
a stage, provided in the chamber, on which a substrate is to be placed; and
a sensor that receives infrared rays emitted from the substrate placed on the stage and that outputs a measurement value corresponding to an intensity of the received infrared rays, the method including
a first determination step of determining that a temperature abnormality of the substrate has occurred when a state in which a time rate of change of the measurement value exceeds a first threshold value persists for a period longer than a threshold time.

### (Technique 8)

The plasma processing method according to Technique 7, further including a second determination step of determining that a temperature abnormality of the substrate has occurred when the measurement value exceeds a second threshold value.

### (Technique 9)

The plasma processing method according to Technique 7 or 8, wherein the plasma processing apparatus further includes:
a plasma generation section that generates plasma in the chamber; and
a gas supply section that supplies a feed gas of the plasma into the chamber, and
the plasma processing method further includes
an operation control step of controlling, after first plasma is generated in the chamber, the plasma generation section and the gas supply section to perform a switching operation for generating second plasma different from the first plasma in the chamber,
wherein the first determination step is performed in a period including a timing at which the switching operation is performed.

### (Technique 10)

The plasma processing method according to Technique 9, wherein in the operation control step, the plasma generation section and the gas supply section are controlled to repeat unit processing including a plurality of steps, and
the first determination step is performed in a period including a period in which the unit processing is repeated.

### (Technique 11)

The plasma processing method according to Technique 10, wherein the unit processing includes:
a deposition step of depositing a protective film on a surface of the substrate;
a protective film removal step of removing a part of the protective film to expose a part of the substrate; and
an etching step of etching the part of the substrate that has been exposed.

### (Technique 12)

The plasma processing method according to Technique 10 or 11, wherein the threshold time is longer than a shortest one of processing times of the plurality of steps.

### INDUSTRIAL APPLICABILITY

The present disclosure can be utilized for plasma processing apparatuses and plasma processing methods.

### REFERENCE NUMERALS

10: Plasma processing apparatus
   11: Stage
      11a: Placement surface
   12: Chamber
      12a: First opening
      12b: Exhaust port
   13: First dielectric member
      13a: Second opening
      13b: Recess
   14: Cover
      14a: Third opening
      14b: First gas introduction path
      14c: Second gas introduction path
      14d: First gas hole
      14e: Second gas hole
   15: Second dielectric member
      15a: Dielectric windows
   16: First induction coil (plasma generation section)
   17: Second induction coil (plasma generation section)
   18: First high-frequency power supply (plasma generation section)
   19: Second high-frequency power supply (plasma generation section)
   21: First matching unit
   22: Second matching unit
   23: Sensor
   24: Gas supply section
   30: Controller
      31: Determination section
      32: Operation control section
S1: First space
S2: Second space
T: Measurement value (temperature of substrate)
T_th: Second threshold value
ΔT: Time rate of change of measurement value
ΔT_th: First threshold value
t_th: Threshold time

What is claimed is:

1. A plasma processing apparatus comprising:
a chamber;
a stage, provided in the chamber, on which a substrate is to be placed;
a sensor that receives infrared rays emitted from the substrate placed on the stage and that outputs a measurement value corresponding to an intensity of the received infrared rays; and
a determination section that determines occurrence or non-occurrence of a temperature abnormality in the substrate based on the measurement value,
wherein the determination section performs first determination processing of determining that a temperature abnormality in the substrate has occurred when a state in which a time rate of change of the measurement value exceeds a first threshold value persists for a period longer than a threshold time.

2. The plasma processing apparatus according to claim 1,
wherein when the measurement value exceeds a second threshold value, the determination section performs second determination processing of determining that a temperature abnormality in the substrate has occurred.

3. The plasma processing apparatus according to claim 1, further comprising:
a plasma generation section that generates plasma in the chamber;
a gas supply section that supplies a feed gas of the plasma into the chamber; and
an operation control section that controls the plasma generation section and the gas supply section,
wherein the operation control section controls, after first plasma is generated in the chamber, the plasma generation section and the gas supply section to perform a switching operation for generating second plasma different from the first plasma in the chamber, and
the determination section performs the first determination processing in a period including a timing at which the switching operation is performed.

4. The plasma processing apparatus according to claim 3,
wherein the operation control section controls the plasma generation section and the gas supply section to repeat unit processing including a plurality of steps, and
the determination section performs the first determination processing in a period including a period in which the unit processing is repeated.

5. The plasma processing apparatus according to claim 4,
wherein the unit processing includes:
a deposition step of depositing a protective film on a surface of the substrate;
a protective film removal step of removing a part of the protective film to expose a part of the substrate; and
an etching step of etching the part of the substrate that has been exposed.

6. The plasma processing apparatus according to claim 4,
wherein the threshold time is longer than a shortest one of processing times of the plurality of steps.

7. A plasma processing method that is executed by a plasma processing apparatus including:
a chamber;
a stage, provided in the chamber, on which a substrate is to be placed; and
a sensor that receives infrared rays emitted from the substrate placed on the stage and that outputs a measurement value corresponding to an intensity of the received infrared rays, the method comprising
a first determination step of determining that a temperature abnormality in the substrate has occurred when a state in which a time rate of change of the measurement value exceeds a first threshold value persists for a period longer than a threshold time.

8. The plasma processing method according to claim 7, further comprising
a second determination step of determining that a temperature abnormality in the substrate has occurred when the measurement value exceeds a second threshold value.

9. The plasma processing method according to claim 7, wherein the plasma processing apparatus further includes:
a plasma generation section that generates plasma in the chamber; and
a gas supply section that supplies a feed gas of the plasma into the chamber, and
the plasma processing method further comprises
an operation control step of controlling, after first plasma is generated in the chamber, the plasma generation section and the gas supply section to perform a switching operation for generating second plasma different from the first plasma in the chamber,
wherein the first determination step is performed in a period including a timing at which the switching operation is performed.

10. The plasma processing method according to claim 9,
wherein in the operation control step, the plasma generation section and the gas supply section are controlled to repeat unit processing including a plurality of steps, and
the first determination step is performed in a period including a period in which the unit processing is repeated.

11. The plasma processing method according to claim 10,
wherein the unit processing includes:
a deposition step of depositing a protective film on a surface of the substrate;
a protective film removal step of removing a part of the protective film to expose a part of the substrate; and
an etching step of etching the part of the substrate that has been exposed.

12. The plasma processing method according to claim 10,
wherein the threshold time is longer than a shortest one of processing times of the plurality of steps.
